(19) United States
(12) Patent Application Publication
(10) Pub. No.: US 2008/0192960 A1
(43) Pub. Date: Aug. 14, 2008

(54) Hybrid Filter for Audio Switching Amplifier

(76) Inventors: Michael B. Nussbaum, Newton, MA (US); Kenneth B. Delpapa, Natick, MA (US)

Correspondence Address: FISH & RICHARDSON PC, P.O. BOX 1022, MINNEAPOLIS, MN, 55440-1022, US

(21) Appl. No.: 11/673,325

(22) Filed: Feb. 9, 2007

(51) Int. Cl. H03F 21/00

(52) U.S. Cl. 381/120

(57) ABSTRACT

An output filter for a switching audio amplifier includes a magnetic core having a gapped central leg and a first and a second outer leg. The central leg and the first outer leg form a first independent magnetic path and the central leg and the second outer leg form a second independent magnetic path. The first and the second outer leg together form a joint magnetic path. A first coil having a first plurality of turns is wound around the first outer leg. A first load current applied to the first coil generates a first magnetic flux in a first direction through the joint magnetic path. A second coil having second plurality of turns is wound around the second outer leg. A second load current applied to the second coil generates a second magnetic flux in a second direction opposite to the first direction through the joint magnetic path.

### BACKGROUND OF THE INVENTION

Switching amplifiers can produce common and differential mode noise. Typically, LC filters are employed to mitigate this noise.

### SUMMARY OF THE INVENTION

In one aspect, an output filter for a switching audio amplifier includes a magnetic core. The magnetic core includes a central leg having a gap and a first and a second outer leg. The central leg and the first outer leg form a first independent magnetic path. The central leg and the second outer leg form a second independent magnetic path. The first and the second outer leg together form a joint magnetic path. The output filter also includes a first coil having a first plurality of turns wound around the first outer leg. A first load current applied to the first coil generates a first magnetic flux in a first direction through the joint magnetic path. The output filter also includes a second coil having second plurality of turns wound around the second outer leg. A second load current applied to the second coil generates a second magnetic flux in a second direction opposite to the first direction through the joint magnetic path.

The switching audio amplifier can be a Bridge Tied Load (BTL) switching amplifier employing a modulation scheme which produces both common mode and differential mode high frequency switching noise. In one embodiment, the first load current is substantially equal to the second load current. The first plurality of turns can be substantially equal to the second plurality of turns. The first magnetic flux and the second magnetic flux can be substantially balanced in the joint magnetic path.

In some embodiments, the first plurality of turns, the second plurality of turns, a dimension of the core, and/or a dimension of the gap is adjusted to set a differential mode inductance. In some embodiments, the first plurality of turns, the second plurality of turns, and a dimension of the core is adjusted to set a common mode inductance.

The magnetic core can be fabricated from a ferrite material. The magnetic core can be formed from two symmetrical parts. Alternatively, the magnetic core can be formed from two or more non-symmetrical parts. The first outer leg can be substantially magnetically identical to the second outer leg. A thickness of the gap can be between substantially 0.05 mm and 5.0 mm. The first coil can be wound in a counterclockwise direction around the first outer leg and the second coil can be wound in a clockwise direction around the second outer leg.

In one embodiment, a capacitor is coupled to at least one of the first coil and the second coil. A terminal of the capacitor can be coupled to ground. In one embodiment, the output filter also includes two common mode capacitors and one differential mode capacitor.

Another aspect is embodied in a method for filtering an output of a switching audio amplifier. The method includes providing a magnetic core having a central leg with a gap and a first and a second outer leg. The central leg and the first outer leg form a first independent magnetic path. The central leg and the second outer leg form a second independent magnetic path. The first and the second outer leg together form a joint magnetic path. A first coil having a first plurality of turns is wound around the first outer leg. A first load current is applied to the first coil to generate a first magnetic flux in a first direction through the joint magnetic path. A second coil having secondary plurality of turns is wound around the second outer leg. A second load current is applied to the second coil to generate a second magnetic flux in a second direction opposite to the first direction through the joint magnetic path.

The switching audio amplifier can be a Bridge Tied Load (BTL) switching amplifier employing a modulation scheme which produces both common mode and differential mode high frequency switching noise. In one embodiment, the first load current can be substantially equal to the second load current. The first plurality of turns can be substantially equal to the second plurality of turns. In one embodiment, the first magnetic flux and the second magnetic flux are substantially balanced in the joint magnetic path.

The method can include adjusting one or more of the first plurality of turns, the second plurality of turns, a dimension of the core, and a dimension of the gap to set a differential mode inductance. The method can also include adjusting one or more of the first plurality of turns, the second plurality of turns, and a dimension of the core to set a common mode inductance. The magnetic core can be fabricated from a ferrite material. In one embodiment, the first outer leg is substantially magnetically identical to the second outer leg. The thickness of the gap can be set to between substantially 0.05 mm and 5.0 mm.

The method can also include coupling at least one capacitor to one of the first coil and the second coil. A terminal of the at least one capacitor can be coupled to ground. The method can also include coupling a common mode capacitor between each of the first and second coils and ground. The method can also include coupling a differential mode capacitor between each of the first and second coils. In one embodiment, the first coil is wound in a counterclockwise direction around the first outer leg and the second coil is wound in a clockwise direction around the second outer leg.

### BRIEF DESCRIPTION OF THE DRAWINGS

This invention is described with particularity in the detailed description. The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1 is a schematic diagram of a conventional filter arrangement which is useful for switching audio amplifiers.

FIG. 2 illustrates a perspective view of one embodiment of a hybrid choke.

FIG. 3A and FIG. 3B illustrate a schematic diagram of the hybrid choke of FIG. 2.

FIG. 4 illustrates a schematic diagram of a hybrid filter for use with an audio amplifier.

FIG. 5 illustrates a schematic drawing of one embodiment of an audio amplifier including the hybrid filter of FIG. 3.

### DETAILED DESCRIPTION

Noise or unwanted signal components generated by electronic circuitry is generally classified into either differential mode noise or common mode noise. In a circuit with two conductors, generally supplying a load, desired differential mode current and undesired differential noise current is current which is carried to the load on one conductor and returned from the load on the second conductor (i.e., the currents flow in an opposite directions with respect to the load). The undesired noise currents can be suppressed by installing a filter in line with either or both of the conductors.

Common mode noise currents are current which are carried to the load by both conductors and return via an alternative path. This alternative path could be parasitic capacitive coupling to a circuit common conductor or electromagnetic radiation. Electromagnetic radiation can cause operational problems with nearby electronic equipment. This type of noise can be suppressed by inserting filters on all lines on which noise is conducted. For example, a common mode choke can include two inductors wound on the same core. One of the inductors is connected in series with one conductor and the other inductor is connected in series with the other conductor.

One fabrication technique for producing a common mode choke coil is by winding a signal wire around a magnetic core. Common mode choke coils behave as an inductor with respect to common mode current. This is due to magnetic fluxes of each coil flowing in a common direction in the core. Thus, common mode choke coils provide large impedance against common mode current and are effective for suppressing common mode noise. The common mode choke offers little impedance to differential current flow. This is due to the magnetic fluxes of each coil flowing in opposite direction in the core and essentially canceling.

The common choke can be used in a filter arrangement. The filter can also include one or more discrete differential mode inductors inserted in one or both of the first conductor and the second conductor. Such a filter also typically includes a first differential mode capacitor connected across the first conductor and second conductor and a common mode capacitor connected from each of the first conductor and the second conductor to ground. A filter arrangement of this type requires six or seven discrete components and a considerable amount of wire length which could either radiate RF noise or receive radiated RF noise. The physical dimensions as well as costs of switching audio amplifiers are constantly being challenged to be reduced, thus filter arrangements with small component sizes, less discrete components and reduced cost are needed.

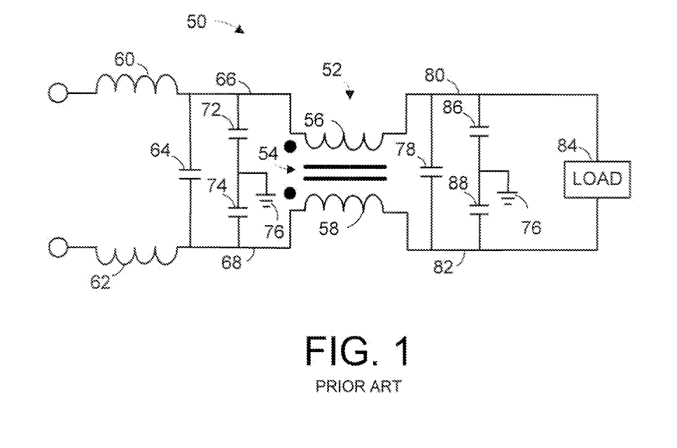

FIG. 1 is a schematic diagram of a conventional filter arrangement 50 which is useful for switching audio amplifiers having a modulation technique which produces both common mode and differential mode noise components such as a class BD amplifier. The filter arrangement 50 has a discrete common mode filter and a differential mode filter. This filter arrangement 50 includes a common mode inductor 52 including a core 54 about which windings 56, 58 are wound in opposite directions. The filter arrangement 50 also includes separate differential mode inductors 60, 62 connected in series with windings of the common mode inductor 52.

The filter also typically includes a differential mode capacitor 64 connected across a first conductor 66 and second conductor 68 between the differential mode inductors 60, 62 and the common mode inductor 52, and common mode capacitors 72, 74 connected from each of the first conductor 66 and the second conductor 68 to ground 76.

The filter also typically includes another differential mode capacitor 78 connected across a first load conductor 80 and a second load conductor 82 between the common mode inductor 52 and the load 84, and common mode capacitors 86, 88 connected from each of the first load conductor 80 and the second load conductor 82 to ground 76.

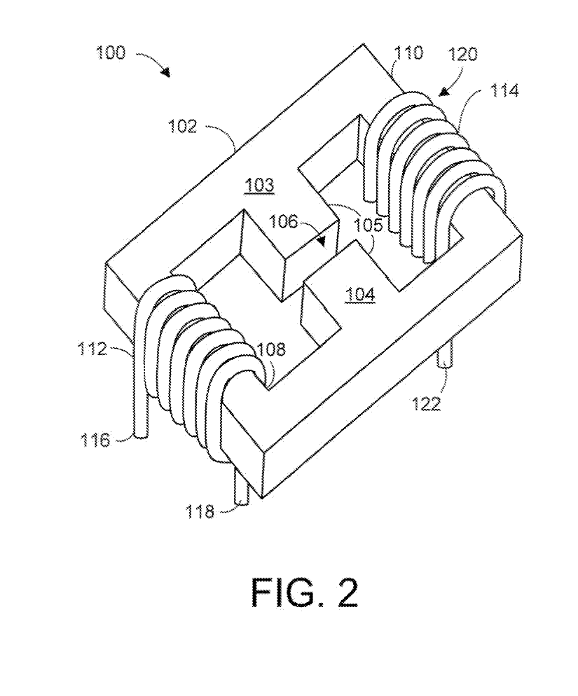

FIG. 2 illustrates a perspective view of one embodiment of a hybrid choke 100. The hybrid choke 100 includes a magnetic core 102 of permeable material. For example, the magnetic core 102 can be fabricated from a ferrite material. The magnetic core 102 can be an E-E magnetic core. The E-E magnetic core is fabricated from two symmetrical halves 103, 104 that are each shaped like a capital letter E. The center leg 105 of the magnetic core 102 can include a gap 106. The size or dimension of the gap 106 can be between anything greater than 0.0 mm (0.05 mm) to about 10.0 mm (and more preferably 5.0 mm). The gap 106 can be an air gap or the gap 106 can include a non-magnetic material. In one embodiment, the first outer leg 108 is substantially magnetically identical to the second outer leg 110. Although the magnetic core 102 is illustrated as two symmetrical E-cores, other embodiments are also contemplated. For example, the core can be fabricated from a combination of an E-core and an I-core. Additionally, a core having any suitable shape can be used.

The dimension of the gap 106 is chosen based on design criteria. For example, the gap 106 in the center leg 105 of the core 102 can be used to adjust the differential mode inductance independent of the common mode inductance. Other dimensions, such as the cross-sectional area of the legs 105, 108, 110 can also affect the common mode inductance and/or the differential mode inductance of the core 102.

A first coil 112 is positioned on the first outer leg 108. A second coil 114 is positioned on the second outer leg 110. The first 112 and the second coils 114 can be wound around the outer legs 108, 110 in opposite directions. For example, the first coil 112 can be wound around the first outer leg 108 in a clockwise direction (starting at end 116 and finishing at end 118) and the second coil 114 can be wound around the second outer leg 110 in a counterclockwise direction (starting at end 120 and a finishing at end 122). In general, terminals 116, 118 are connected in series with a signal line or a conductor and terminals 120, 122 are connected in series with a return signal line or a conductor.

The outer perimeter of the magnetic core 102 can be referred to as the common mode path. The magnetic flux in the outer perimeter of the magnetic core 102 resulting from a common mode current in the first coil 112 flows in the same direction as the magnetic flux in the outer perimeter of the magnetic core 102 resulting from a common mode current in the second coil 114. Thus, the two magnetic fluxes substantially add to each other thereby providing a large common mode inductance. The common mode noise current flows in the same direction in each of the first coil 112 (from end 116 to end 118) and the second coil 114 (from end 120 to end 122).

The outer legs 108, 110 along with the gapped center leg 105 provide the differential mode path. The differential mode path is a different flux path than the common mode path. Differential currents are carried to the load on one conductor and returned from the load on a second conductor. The differential currents on the conductors are equal and opposite in magnitude (differential current includes both desired load current and differential noise current). In FIG. 2, differential current flows through the first coil 112 from end 116 to end 118, then through the load and returns through the second coil 114 from end 122 to end 120. These current flows create fluxes of equal and opposite direction in the first outer leg 108 and the second outer leg 110. The opposing fluxes meet at the center leg 105 and travel through the center leg 105 and through the gap 106 to return to their respective coils 112, 114. The gap 106 can be adjusted to control saturation as well as inductance.

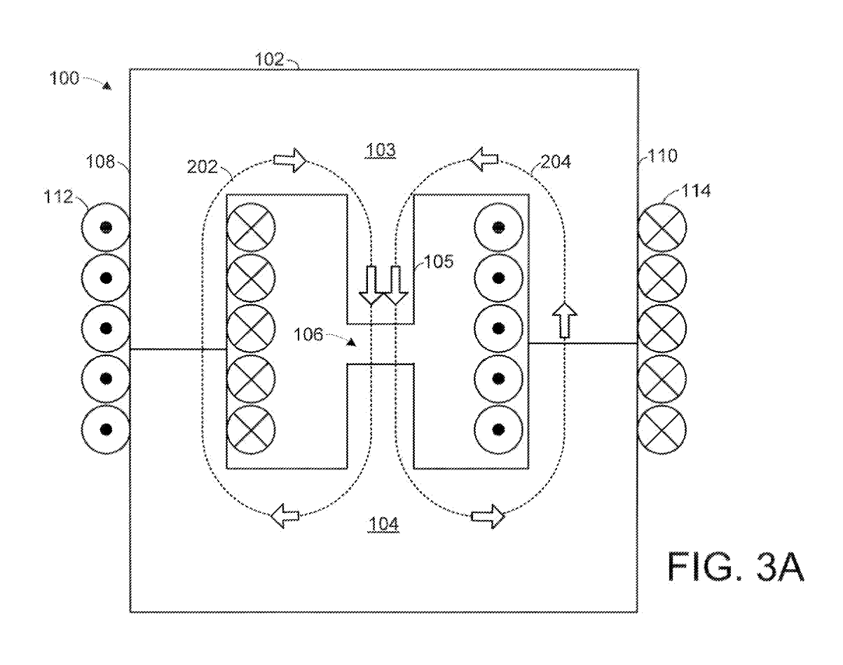

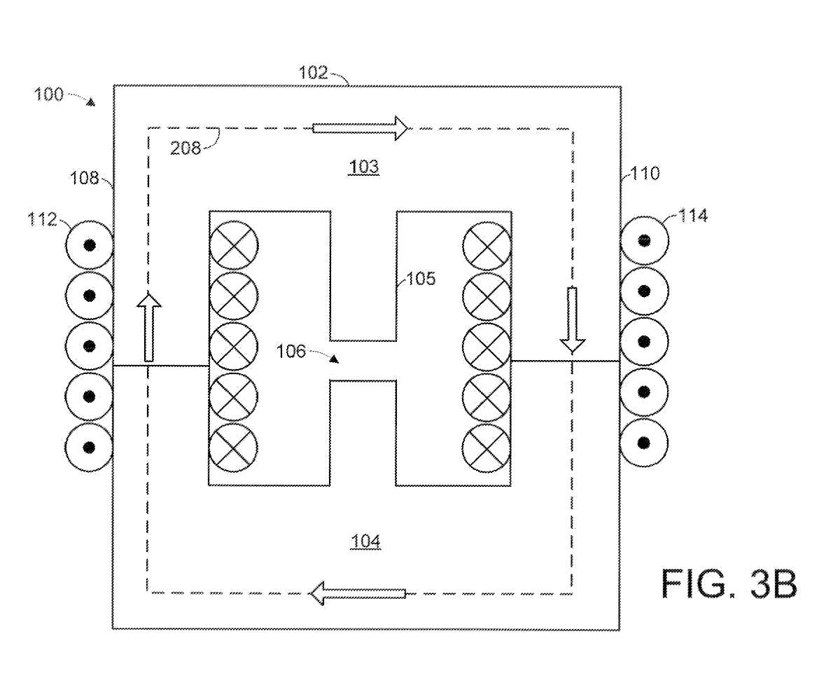

FIG. 3A and FIG. 3B illustrate a schematic diagram of the hybrid choke 100 of FIG. 2. The first coil 112 is wound around the first outer leg 108 and the second coil 114 is wound around the second outer leg 110. In FIG. 3A, the paths 202, 204 of the magnetic flux of the differential-mode signals are shown by arrows. In FIG. 3B, the path 208 of the magnetic flux of the common-mode signals are shown by arrows. As previously described, the choke 100 utilizes one core frame and the two coils 112, 114 can be wound on the same core frame. The differential-mode inductance value can be adjusted by varying the size of the gap 106 of the core 102. The common-mode inductance value is generally not affected by varying the size of the gap 106. In addition, the paths 202, 204 of differential-mode flux and the path 208 (FIG. 3B) of the common-mode flux partially overlap. Therefore, the common-mode inductance value can be somewhat influenced by the differential-mode flux since the differential-mode flux can decrease the effective permeability of the magnetic core.

In FIG. 3A, the magnetic flux path 202 is the flux path for a first differential inductor created by a current flow in coil 112. The current flow out of the page is indicated by a dot and current flow into the page is indicated by a X. Magnetic flux path 202 passes through the first outer leg 108, a portion of the upper E-core 103, the center leg 105, the gap 106 and a portion of the lower E-core 104. Thus, the first coil 112 in combination with E-cores 103, 104 functions as a differential inductor.

Magnetic flux path 204 is the flux path for a second differential inductor is created by a current flow in coil 114. The current flow out of the page is indicated by a dot and current flow into the page is indicated by a X. Magnetic flux path 204 passes through the second outer leg 110, a portion of the upper E-core 103, the center leg 105, the gap 106 and a portion of the lower E-core 104. Thus, the second coil 114 in combination with E-cores 103, 104 functions as a differential inductor.

In FIG. 3B, the magnetic flux path 208 is created by the current flows in coil 112 and coil 114. The current flow out of the page is indicated by a dot and current flow into the page is indicted by a X. The magnetic fluxes from both coils travel in a common path passing through the first outer leg 108, a portion of the upper E-core 103, the second outer leg 110 and a portion of the lower E-core 104. Since the first coil 112 and the second coil 114 are wound oppositely, the magnetic fluxes generated by the coils 112, 114 travel in opposite directions with respect to each coil leg. The fluxes unite the coils 112, 114. Thus, coils 112, 114 in combination with E-cores 103, 104 function as common mode inductors.

Adjustment of the gap 106 along with altering the number of turns of coils 112, 114 results in an ability to adjust the inductances of the differential inductors. Altering the number of turns of coils 112, 114 also affects the inductances of the common mode inductors. The hybrid choke 110 will always have a larger common mode inductance than differential inductance.

The inductance of the first differential inductor is determined by the number of turns in the first coil 112, the cross-sectional area of the core, the magnetic length of the core, the permeability of the core, and the size of the gap 106. The inductance of the second differential inductor is determined by the number of turns in the second coil 114, the cross-sectional area of the core, the magnetic length of the core, the permeability of the core, and the size of the gap 106. The inductance of the first common mode inductor is determined by the number of turns of the first coil 112, the magnetic length of the core, the permeability of the core, and the cross-sectional-area of the core. The inductance of the second common mode inductor is determined by the number of turns of the second coil 14, the magnetic length of the core, the permeability of the core, and the cross-sectional-area of the core.

By varying the number of turns of winding 112, 114 and the dimension of the gap 106, the inductance of the differential mode and the common mode inductors can be changed. In one embodiment, the inductance of the differential inductors can be established independent of the inductance of common mode inductors.

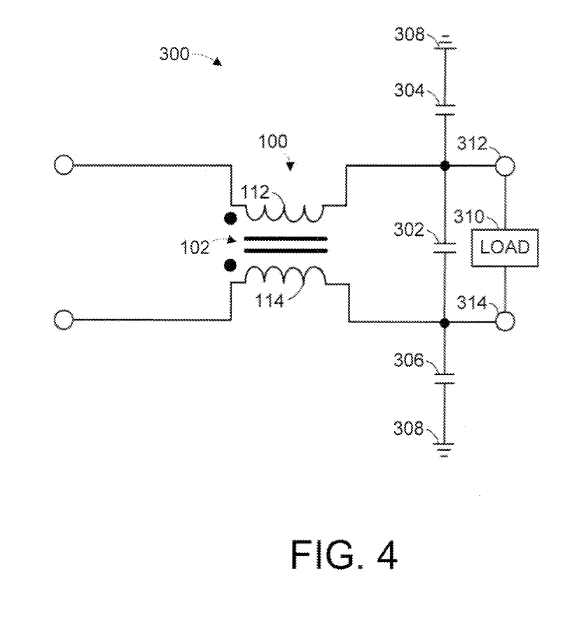

FIG. 4 illustrates a schematic diagram of a hybrid filter 300 for use with an audio amplifier. The hybrid filter 300 utilizes the hybrid choke 100 of FIG. 2. The hybrid filter 300 also includes a differential mode filter capacitor 302 and common-mode filter capacitors 304 and 306. Capacitors 304 and 306 are preferably coupled to ground 308. One or more electrical loads 310 are coupled to first 312 and second output terminals 314 of the hybrid filter 300.

The hybrid filter 300 operates as follows. Differential mode current flows through the first coil 112, is divided between the differential mode filter capacitor 302 and the load 310, and flows through the second coil 114. The capacitor 302 shunts the high frequency components of the current from the load. The combination of the first coil 112 and the second coil 114 encompass a single inductor which behaves as a differential mode inductor. The combined number of turns in the first coil 112 and the second coil 114 are selected (in view of the geometry of the core of the hybrid choke 110) to provide the desired differential mode inductance. This provides a very compact inductor design. It should be noted that some differential mode current also flows through the common-mode filter capacitors 304 and 306.

The ability of creating a differential and common mode inductor on a common core has the benefit of significantly reducing the component count (as can be seen compared to FIG. 1) required to implement the filter. This is particularly beneficial since inductors are typically the largest and most expensive of the filter components.

Common mode currents flow through different paths. Specifically, the first common mode current flows through the first coil 112, the common mode filter capacitor 304, and then to ground 308. The second common mode current flows through the second coil 114, the common mode filter capacitor 306, and then to ground 308. If the core 102 is substantially symmetric and the common mode filter capacitors 304, 306 are substantially the same value, then the number of turns in the first coil 112 and the second coils 114 are chosen to the equal.

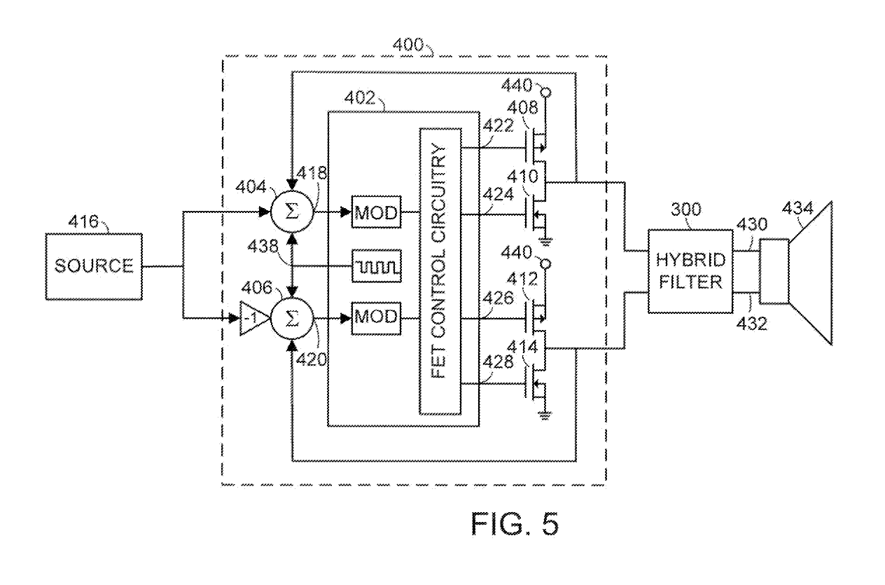

FIG. 5 illustrates a schematic drawing of one embodiment of an audio amplifier 400 including the hybrid filter 300 of FIG. 4. The audio amplifier 400 includes a modulator integrated circuit (IC) 402, first and second summing modules 404, 406, and transistors 408, 410, 412, 414.

The summing module 404 receives an audio signal from an audio source 416 and combines it with an output from the transistor pair 408, 410 as well as a modulation oscillator signal 438. The summing module 406 receives an inverted audio signal from the audio source 416 and combines it with an output from the transistor pair 412, 414 as well as a modulation oscillator signal 438. The outputs 418, 420 of the summing modules 404, 406 are coupled to the modulator IC 402. The outputs 422, 424, 426, 428 of the modulator IC 402 are coupled to the transistors 408, 410, 412, 414. The sources of transistor 408, 412 are connected to a positive power supply voltage 440. The outputs of the transistor pairs 408, 410 and 412, 414 are coupled to the hybrid filter 300. In one embodiment, the hybrid filter 300 can also include band-pass filter circuitry (not shown) or any filter circuitry that provides a desired frequency response. The outputs 430, 432 of the hybrid filter 300 are coupled to a transducer 434.

The audio amplifier 400 can embody a switching amplifier. In one embodiment, the hybrid filter 300 is especially useful in suppressing common mode and differential mode noise in a Bridge Tied Load (BTL) switching amplifier employing a modulation scheme which produces both common mode and differential mode high frequency switching noise for example a BD BTL audio amplifier. The audio amplifier 400 can have unipolar or bipolar supply voltages. In the embodiment shown, the audio amplifier 400 is a unipolar supply, BTL class BD switching amplifier.

The foregoing description is intended to be merely illustrative of the present invention and should not be construed as limiting the appended claims to any particular embodiment or group of embodiments. Thus, while the present invention has been described with reference to exemplary embodiments, it should also be appreciated that numerous modifications and alternative embodiments may be devised by those having ordinary skill in the art without departing from the broader and intended spirit and scope of the present invention as set forth in the claims that follow. In addition, the section headings included herein are intended to facilitate a review but are not intended to limit the scope of the present invention. Accordingly, the specification and drawings are to be regarded in an illustrative manner and are not intended to limit the scope of the appended claims.

In interpreting the appended claims, it should be understood that:

a) the word “comprising” does not exclude he presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) any of the disclosed elements may be comprised of hardware portions (e.g., including discrete and integrated electronic circuitry), software portions (e.g., computer programming), and any combination thereof;

f) hardware portions may be comprised of one or both of analog and digital portions;

g) any of the disclosed devices or portions thereof may be combined together or separated into further portions unless specifically stated otherwise; and
h) no specific sequence of acts or steps is intended to be required unless specifically indicated.

What is claimed is:

1. An output filter for a switching audio amplifier comprising:
a magnetic core comprising a central leg having a gap and a first and a second outer leg, the central leg and the first outer leg forming a first independent magnetic path and the central leg and the second outer leg forming a second independent magnetic path, the first and the second outer leg together forming a joint magnetic path;
a first coil having a first plurality of turns wound around the first outer leg, a first load current applied to the first coil generating a first magnetic flux in a first direction through the joint magnetic path; and
a second coil having second plurality of turns wound around the second outer leg, a second load current applied to the second coil generating a second magnetic flux in a second direction opposite to the first direction through the joint magnetic path.

2. The output filter of claim 1 wherein the switching audio amplifier comprises a Bridge Tied Load (BTL) switching amplifier employing a modulation scheme which produces both common mode and differential mode high frequency switching noise.

3. The output filter of claim 1 wherein the first load current is substantially equal to the second load current.

4. The output filter of claim 1 wherein the first plurality of turns is substantially equal to the second plurality of turns.

5. The output filter of claim 1 wherein the first magnetic flux and the second magnetic flux are substantially balanced in the joint magnetic path.

6. The output filter of claim 1 wherein at least one of the first plurality of turns, the second plurality of turns, a dimension of the core, and a dimension of the gap is adjusted to set a differential mode inductance.

7. The output filter of claim 1 wherein at least one of the first plurality of turns, the second plurality of turns, and a dimension of the core is adjusted to set a common mode inductance.

8. The output filter of claim 1 wherein the magnetic core is fabricated from a ferrite material.

9. The output filter of claim 1 wherein the magnetic core is formed from two symmetrical parts.

10. The output filter of claim 1 wherein the first outer leg is substantially magnetically identical to the second outer leg.

11. The output filter of claim 1 wherein a thickness of the gap is between substantially 0.05 mm and 5.0 mm.

12. The output filter of claim 1 further comprising at least one capacitor that is coupled to at least one of the first coil and the second coil.

13. The output filter of claim 12 wherein a terminal of the at least one capacitor is coupled to ground.

14. The output filter of claim 1 further comprising two common mode capacitors and one differential mode capacitor.

15. The output filter of claim 1 wherein the first coil is wound in a counterclockwise direction around the first outer leg and the second coil is wound in a clockwise direction around the second outer leg.

16. A method for filtering an output of a switching audio amplifier, the method comprising the acts of:
providing a magnetic core comprising a central leg having a gap and a first and a second outer leg, the central leg and the first outer leg forming a first independent magnetic path and the central leg and the second outer leg forming a second independent magnetic path, the first and the second outer leg together forming a joint magnetic path;
winding a first coil having a first plurality of turns around the first outer leg;
applying a first load current to the first coil to generate a first magnetic flux in a first direction through the joint magnetic path;
winding a second coil having second plurality of turns around the second outer leg; and
applying a second load current to the second coil to generate a second magnetic flux in a second direction opposite to the first direction through the joint magnetic path.

17. The method of claim 16 wherein the switching audio amplifier comprises Bridge Tied Load (BTL) switching amplifier employing a modulation scheme which produces both common mode and differential mode high frequency switching noise.

18. The method of claim 16 wherein the first load current is substantially, equal to the second load current.

19. The method of claim 16 wherein the first plurality of turns is substantially equal to the second plurality of turns.

20. The method of claim 16 wherein the first magnetic flux and the second magnetic flux are substantially balanced in the joint magnetic path.

21. The method of claim 16 further comprising adjusting at least one of the first plurality of turns, the second plurality of turns, a dimension of the core, and a dimension of the gap to set a differential mode inductance.

22. The method of claim 16 further comprising adjusting at least one of the first plurality of turns, the second plurality of turns, and a dimension of the core to set a common mode inductance.

23. The method of claim 16 wherein the magnetic core is fabricated from a ferrite material.

24. The method of claim 16 wherein the first outer leg is substantially magnetically identical to the second outer leg.

25. The method of claim 16 further comprising setting the thickness of the gap between substantially 0.05 mm and 5.0 mm.

26. The method of claim 16 further comprising coupling at least one capacitor to at least one of the first coil and the second coil.

27. The method of claim 26 further comprising coupling a terminal of the at least one capacitor to ground.

28. The method of claim 16 further comprising coupling a common mode capacitor between each of the first and second coils and ground.

29. The method of claim 16 further comprising coupling a differential mode capacitor between each of the first and second coils.

30. The method of claim 16 wherein the first coil is wound in a counterclockwise direction around the first outer leg and the second coil is wound in a clockwise direction around the second outer leg.

31. An output filter for a switching audio amplifier comprising:
means for providing a magnetic core comprising a central leg having a gap and a first and a second outer leg, the central leg and the first outer leg forming a first independent magnetic path and the central leg and the second outer leg forming a second independent magnetic path, the first and the second outer leg together forming a joint magnetic path;
means for winding a first coil having a first plurality of turns around the first outer leg;
means for applying a first load current to the first coil to generate a first magnetic flux in a first direction through the joint magnetic path;
means for winding a second coil having second plurality of turns around the second outer leg; and
means for applying a second load current to the second coil to generate a second magnetic flux in a second direction opposite to the first direction through the joint magnetic path.
